(19) United States
(12) Patent Application Publication
(10) Pub. No.: US 2026/0182184 A1
(43) Pub. Date: Jun. 25, 2026

(54) DISPLAY PANEL

(71) Applicant: LG Display Co., Ltd., Seoul (KR)

(72) Inventors: Hoe Yong KIM, Paju-si (KR); Ki Min CHOI, Paju-si (KR)

(73) Assignee: LG Display Co., Ltd., Seoul (KR)

(21) Appl. No.: 19/402,029

(22) Filed: Nov. 26, 2025

(30) Foreign Application Priority Data
Dec. 24, 2024 (KR) 10-2024-0195826

(51) Int. Cl. H10K 59/131; H10K 59/80

(52) U.S. Cl. CPC H10K 59/131; H10K 59/873; H10K 59/8794

(57) ABSTRACT

A display panel according to an embodiment of the present disclosure includes a substrate, a pad arranged at a first side of the substrate, a low-potential voltage pattern arranged on the substrate and electrically connected to the pad, a conductive encapsulation layer arranged on the low-potential voltage pattern, and a connection structure configured to electrically connect the low-potential voltage pattern and the conductive encapsulation layer.

### CROSS-REFERENCE TO RELATED APPLICATION

This application claims priority to and the benefit of Korean Patent Application No. 10-2024-0195826, filed Dec. 24, 2024, the disclosure of which is incorporated herein by reference in its entirety.

### BACKGROUND

### Field

The present specification relates to a display panel, and more particularly to a display panel capable of reducing heat generation thereof.

### Discussion of Related Art

With the advent of the full-fledged information age, the field of display devices that visually represent electrical information signals has been rapidly advancing. As a result, research to develop the performance of display devices, such as reduced thickness, lighter weight, low power consumption, and the like, is underway.

Representative examples of display devices may include Liquid Crystal Display (LCD) apparatuses, Organic Light Emitting Display (OLED) apparatuses, quantum dot display apparatuses, and the like.

A display panel of a display device may include a pad to which a driving voltage or a common voltage is applied. A link to which a driving voltage or a common voltage is applied may be electrically connected to the pad. Also, a plurality of signal wires or electrode patterns configured to transfer signals to a display area may be electrically connected to the link.

Here, the link includes electrode patterns or a plurality of signal wires integrated in a limited space, which may result in an increase in current density. The increased current density may cause heat generation in the display panel.

### SUMMARY

A display panel according to an example embodiment connects a conductive encapsulation layer, which is an encapsulation layer for a light-emitting element, to an electrode pattern so as to lower current density, thereby reducing heat generation of the display panel.

The aspects of the present specification are not limited to the foregoing aspects, and additional aspects, which are not mentioned herein, will be described in the following description or be apparent to those skilled in the art from the following description.

To achieve these and other advantages and in accordance with an aspect of the present specification, as embodied and broadly described herein, a display panel according to an example embodiment of the present specification may include a substrate, a pad arranged at a first side of the substrate, a low-potential voltage pattern arranged on the substrate and electrically connected to the pad, a conductive encapsulation layer arranged on the low-potential voltage pattern, and a connection structure configured to electrically connect the low-potential voltage pattern and the conductive encapsulation layer.

In another aspect, a display panel according to an example embodiment of the present specification may include a substrate including a display area, a first peripheral area around the display area, and a second peripheral area around the first peripheral area; a pad arranged at a first side of the substrate; an auxiliary voltage line arranged on the first peripheral area of the substrate and electrically connected to the pad; a heat-dissipating electrode arranged on the second peripheral area of the substrate; a connection pattern arranged on the first and second peripheral areas of the substrate and configured such that a first side thereof is connected to the auxiliary voltage line and a second side thereof is connected to the heat-dissipating electrode; a conductive encapsulation layer located in the display area and first peripheral area of the substrate and arranged on the auxiliary voltage line; and a connection member configured such that a first side thereof is connected to the heat-dissipating electrode and a second side thereof is connected to the conductive encapsulation layer.

The display panel according to one or more example embodiments of the present specification may have the effect of reducing heat generation of the display panel.

The effects of the present specification are not limited to the effects mentioned above, and other effects not mentioned will be apparent from the following description to one having ordinary skill in the art to which the technical ideas of the present specification belong.

### BRIEF DESCRIPTION OF THE DRAWINGS

The accompanying drawings, which are included to provide a further understanding of the present specification and are incorporated in and constitute a part of this application, illustrate example embodiments of the present specification and together with the description serve to explain various principles of the specification. In the drawings:

FIG. 1 is a plan view of a display panel according to one or more example embodiments of the present specification;

FIG. 2 is a circuit diagram of a sub-pixel according to one or more example embodiments;

FIG. 3A is a plan view of a display panel according to an example embodiment of the present specification;

FIG. 3B is an enlarged plan view of area A of FIG. 3A;

FIG. 3C is an enlarged plan view of area B of FIG. 3A;

FIG. 4 is a plan view of a display panel according to a first example embodiment of the present specification;

FIG. 5 is a cross-sectional view taken along the line I-I′ in FIG. 4;

FIG. 6 is a cross-sectional view of a light-emitting element according to an example embodiment;

FIG. 7 is a plan view of a display panel according to a second example embodiment of the present specification;

FIG. 8 is a cross-sectional view taken along the line II-II′ of FIG. 7; and

FIG. 9 is a plan view of a display panel according to a third example embodiment of the present specification.

### DETAILED DESCRIPTION

The advantages and features of the present disclosure, and methods for achieving them will become apparent from the example embodiments described below in detail in conjunction with the accompanying drawings. However, the present disclosure is not limited to the example embodiments disclosed herein, but may be implemented in various different forms. The example embodiments are provided to make the disclosure of the present disclosure more complete and to enable those skilled in the art to comprehend the scope of the present disclosure more fully.

The shapes, sizes, proportions, angles, numbers, and the like of elements shown in the drawings to illustrate example embodiments of the present disclosure are merely illustrative and are not intended to be limiting. Identical reference numerals may designate identical components throughout the description. Further, in describing the present disclosure, detailed descriptions of well-known technologies may be omitted so as not to obscure aspects or features of the present disclosure.

Terms such as “comprising,” “including,” “having,” and “consisting of” as used herein are generally intended to allow for the addition of other components, unless the terms are used with a more specific term like “only.” References to components of a singular noun include the plural of that noun, and vice versa, unless specifically stated otherwise.

In the description of components, they are to be interpreted to include margins of error even where not explicitly stated.

Where the positional relationship is described, for example, if the positional relationship of the two parts is described as “on the top,” “above,” “below,” “next to,” etc., one or more other parts may be located between the two parts unless a more specific term like “directly” is used.

Where an element or layer is described as disposed “on” another element or layer, the element or layer may be disposed directly on another element or layer or may be indirectly disposed on another element or layer with still another element or layer therebetween.

Terms like “first,” “second,” etc., are used to describe various components, but these components are not limited by these terms. These terms are used only to refer to one component separately from another. Therefore, the first component referred to below may be a second component, an vice versa, within the technical spirit of the present disclosure.

Like reference numerals generally denote like elements throughout the specification.

The size and thickness of each component illustrated in the drawings are shown for convenience of description, and the present disclosure is not necessarily limited to the size and thickness of the component illustrated.

The features of various embodiments of the present disclosure can be partially or entirely bonded to or combined with each other. The embodiments can be interoperated and performed in various ways technically and can be carried out independently of or in association with each other.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

A transistor used in a display device according to exemplary embodiments of the present disclosure may be implemented as any one transistor of an n-channel transistor (NMOS) and a p-channel transistor (PMOS). The transistor may be implemented as an oxide semiconductor transistor having an oxide semiconductor as an active layer or a low temperature poly-silicon (LTPS) transistor having LTPS as the active layer. The transistor may at least include a gate electrode, a source electrode, and a drain electrode. The transistor may be implemented as a thin film transistor (TFT) on a display panel. A carrier in the transistor flows from a source electrode to a drain electrode. In the case of the n-channel transistor (NMOS), since the carrier is an electron, a source voltage may be lower than a drain voltage so that the electron may flow from the source electrode to the drain electrode. In the n-channel transistor (NMOS), a current may flow from the drain electrode to the source electrode, and the source electrode may be an output terminal. In the case of the p-channel transistor (PMOS), since the carrier is a hole, the source voltage may be higher than the drain voltage so that the hole may flow from the source electrode to the drain electrode. Since the hole flows from the source electrode to the drain electrode in the p-channel transistor (PMOS), the current may flow from a source electrode to a drain electrode, and the drain electrode may be the output terminal. Accordingly, it should be noted that since the source and the drain may be changed according to an applied voltage, the source and the drain of the transistor are not fixed. In the present disclosure, a description is made by assuming that the transistor is the n-channel transistor (NMOS), but the present disclosure is not limited thereto, but the p-channel transistor may be used, and as a result, a circuit configuration may also be changed.

As used herein, “a device” may include a display apparatus, such as a liquid crystal module (LCM) or an organic light emitting display (OLED) module, which includes a display panel and a driver for driving the display panel. It may also include a set electronic device or a set device, such as a laptop computer, a television set, a computer monitor, a vehicle or an automotive device, or an equipment device including another form of vehicle, and a mobile electronic device, such as a smart phone or an electronic pad and the like, which is a complete product or finished product including LCMs, OLED modules, and the like.

Accordingly, the apparatus or device as described herein may include a display apparatus itself, such as an LCM or OLED module, and an application product, as well as a set device, an end user device that includes the LCM or the OLED module.

Furthermore, in some embodiments, the LCM and OLED module including the display panel and the driver may be expressed as a “display apparatus,” the electronic device may be expressed as a finished product including the LCM and OLED module that may be expressed as a “set device.” For example, a display apparatus may include a liquid crystal display (LCD) panel or an organic light emitting display (OLED) panel, and a source PCB (printed circuit board) which is a control part for driving the display panel. The set device may further include a set PCB, which is a set control part electrically connected to the source PCB to drive the entire set device.

The display panel used in embodiments of the present disclosure may be any type of display panel, including, but not limited to, a liquid crystal display panel, an organic light emitting diode (OLED) display panel, and an electroluminescent display panel. The display panel applicable to the display apparatus according to embodiments of the present disclosure is not limited to the shape or size of the display panel.

Each of the features of the various embodiments described herein may be coupled or combined with one another in whole or in part and may be technologically interlocked and operated in various ways, and each of the embodiments may be carried out independently or in conjunction with one another.

Hereinafter, various example embodiments of the present disclosure will be described in detail with reference to the accompanying drawings. The dimensions of the components shown in the drawings are for illustrative purposes only and are not necessarily to scale with the actual components shown in the drawings.

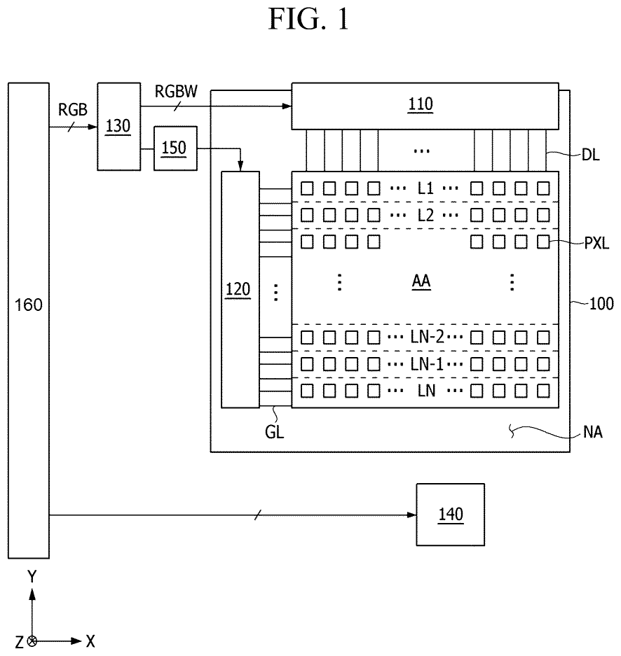

FIG. 1 is a plan view for a display panel of the present specification according to one or more example embodiments.

As shown in FIG. 1, a horizontal direction X and a vertical direction Y of a display panel 100 may be a length direction and a width direction of the display panel 100, respectively. Further, the horizontal direction X and the vertical direction Y of the display panel 100 may also be represented by a row direction and a column direction, respectively. A thickness direction Z may refer to a direction perpendicular to a plane defined by the horizontal direction X and the vertical direction Y of the display panel 100. The display panel 100 may have a cross-section in the thickness direction Z.

As shown in FIG. 1, the display panel 100 according to one or more example embodiments of the present disclosure may include a display panel driving circuit for writing pixel data to pixels, and a power supply 140 for generating power for driving the pixels and the display panel driving circuit.

A display area AA of the display panel 100 may include a pixel array for displaying an input image thereon. The pixel array may include a plurality of data lines DL, a plurality of gate lines GL crossing the data lines DL, and pixels arranged in a matrix form. The display panel 100 may include power lines commonly connected to the pixels. The power lines may be commonly connected to constant voltage nodes of pixel circuits and supply constant voltages for driving the pixels PXL. The power lines may be implemented as striped or mesh wires to be connected in common to the pixels of the display panel 100.

Each of the pixels PXL may include a first sub-pixel, a second sub-pixel, a third sub-pixel, and a fourth sub-pixel of different colors for color implementation. The color arrangement of the sub-pixels may be changed. The first sub-pixel may be, but is not limited to, a blue (B) sub-pixel, the second sub-pixel may be a green (G) sub-pixel, the third sub-pixel may be a red (R) sub-pixel, and the fourth sub-pixel may be a white (W) sub-pixel.

Each of the sub-pixels may include a pixel circuit to drive a light-emitting element. Each of the pixel circuits may be connected to the data lines, the gate lines, and the power lines. Each sub-pixel may be divided into a circuit area and a light-emitting area. The pixel circuit may be located in the circuit area. The light-emitting area may be the area from which light is emitted by a light-emitting element electrically connected to the pixel circuit.

The pixel array may include a plurality of pixel lines L1 to LN. Each of the pixel lines L1 to LN may include one line of pixels arranged along the X-axis direction in the pixel array of the display panel 100. The pixels arranged in one pixel line may share the gate lines GL. The sub-pixels arranged in the column direction (Y) along a data line direction may share the same data line DL. One horizontal period is a time obtained by dividing one frame period by the total number of the pixel lines L1 to LN.

The power supply 140 outputs voltages for driving the pixels and the display panel driving circuit of the display panel 100 by using a direct current (DC)-to-direct current DC) converter (DC-DC converter). The DC-DC converter may include a charge pump, a regulator, a buck converter, a boost converter, and the like.

The display panel driving circuit writes the pixel data of an input image to the pixels of the display panel 100 under the control of a timing controller 130. The display panel driving circuit includes a data driver 110 and a gate driver 120.

The display panel driving circuit may drive the pixels with double rate driving (DRD). In a DRD-driven display panel, the data lines DL are connected to neighboring sub-pixels on the left and right, reducing the number of channels in the data driver 110 and the number of data lines DL, which is advantageous for ensuring the aperture ration of the pixels.

The display panel driving circuit may further include a touch sensor driver for driving the touch sensors. The touch sensor driver is omitted from FIG. 1. The data driver 110 and the touch sensor driver may be integrated into one source drive IC (Integrated Circuit).

The data driver 110 may receive pixel data of the input image received as a digital signal from the timing controller 130 and output a data voltage. The data driver 110 may output the data voltage by converting the pixel data of the input image into a gamma compensated voltage every frame period using a digital-to-analog converter (DAC). The data voltage may be outputted from each of the channels of the data driver 110 through an output buffer.

The gate driver 120 may be formed in the display panel 100 together with a TFT array of the pixel array and the wires. The gate driver 120 may be located on a non-display area NA adjacent to the display area AA of the display panel 100, or at least some of the gate driver may be located within a display area AA in which an input image is reproduced.

In one or more aspects, the gate driver 120 may be connected to the display panel 100 by the tape-automated-bonding (TAB) technique, or connected to a conductive pad such as a bonding pad of the display panel 100 by the chip-on-glass (COG) technique or the chip-on-panel (COP) technique, or connected to the display panel 110 by the chip-on-film (COF) technique. In one or more aspects, the gate driver 120 may be disposed in the non-display area NA of the display panel 100 by a gate-in-panel (GIP) technique, without being limited thereto. Alternatively, the gate driver 120 may be disposed in the display area AA of the display panel 100.

The gate driver 120 may be located in the non-display areas NA on both sides of the display panel 100 with the display area AA of the display panel interposed therebetween, and it may supply gate pulses from both sides of the gate lines GL in a double feeding method. In another example embodiment, the gate driver 120 may be located in at least one of the left and right non-display areas NA of the display panel 100 and may supply gate signals to the gate lines GL in a single feeding method. The gate driver 120 sequentially outputs pulses of the gate signals (hereinafter referred to as “gate pulses”) to the gate lines 103 under the control of the timing controller 130. The gate driver 120 may shift the gate pulses using a shift register to sequentially supply the gate pulses to the gate lines GL. The gate driver 120 may include one or more shift registers that output the pulses of the gate signals.

The timing controller 130 receives digital video data of the input image and a timing signal synchronized with the digital video data from the host system 160. The timing signal may include a vertical synchronization signal, a horizontal synchronization signal, a clock and a data enable signal. A vertical period and a horizontal period may be known by counting the data enable signal, and thus the vertical synchronization signal and the horizontal synchronization signal may be omitted. The data enable signal has a cycle of one horizontal period (1H). The timing controller 130 generates a data timing control signal for controlling the operation timing of the data driver 110 and a gate timing control signal for controlling the operation timing of the gate driver 120 based on the timing signals signal received from the host system 160.

The timing controller 130 may add white color data to the three primary colors of pixel data RGB input from the host system and convert it to four sub-color data RGBW for transmission to the data driver 110. Any known color conversion algorithm may be used to convert the three primary colors of pixel data RGB into four sub color data RGBW including the white color data.

For example, the timing controller 130 may convert the first pixel data to four sub-color data RGBW by generating the W data of the first pixel data based on the minimum grayscale value among the R data, G data, and B data of the first pixel data received as data of the input image. Further, the timing controller 130 may convert the second pixel data to four sub-color data RGBW by generating the W data of the second pixel data based on the minimum grayscale value among the R data, G data, and B data of the second pixel data received as data of the input image.

For each of the first pixel data and the second pixel data, the grayscale values of the R, G, and B data may be lowered by the W data. Here, R data is data to be written to the red sub-pixel, and G data is data to be written to the green sub-pixel. B data is data to be written in the blue sub-pixel, and data W is data to be written in the white sub-pixel.

The level shifter 150 may receive the gate timing control signal from the timing controller 130 and generate a start pulse and a shift clock to provide them to the gate driver 120. The start pulse and the shift clock output from the level shifter 150 swing between the gate-high voltage and the gate-low voltage. In another example, the level shifter 150 may be formed or integrated into the gate driver 120.

The host system 160 may include a main board of any of a television system, a set-top box, a navigation system, a personal computer (PC), an in-vehicle system, a mobile terminal, or a wearable terminal. The host system may scale an image signal from a video source to match the resolution of the display panel 100 and may transmit it to the timing controller 130 together with the timing signal.

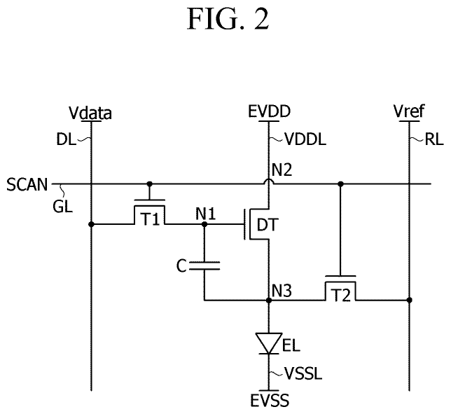

FIG. 2 is a circuit diagram for a sub-pixel circuit according to one or more example embodiments.

As shown in FIG. 2, a circuit for each of sub-pixels PXL (hereinafter referred to as a sub-pixel circuit) may be connected to a data line DL to which a data voltage Vdata of pixel data is applied, a gate line GL to which a gate pulse SCAN is applied, a driving voltage line VDDL to which a pixel driving voltage EVDD is applied, a low-potential voltage line VSSL to which a low-potential voltage EVSS is applied, and a reference voltage line RL to which a reference voltage Vref is applied.

Each sub-pixel circuit may include a light-emitting element EL, a plurality of transistors DT, T1, and T2, and a capacitor C. However, in the display panel described herein, the sub-pixel circuit configuration is not limited thereto. For example, the sub-pixel circuit of the present disclosure may include more or less elements than shown. For example, 4T1C, 5T1C, 3T2C, 4T2C, 5T2C, 6T2C, 7T1C, 7T2C, 8T1C, 8T2C structures, etc. are also possible. And more or less transistors and capacitors could be included.

The light-emitting element may be an organic light-emitting diode (OLED) or an inorganic light-emitting element such as micro LED. The light-emitting element EL may include, but not limited to, a red light-emitting element, a green light-emitting element, and a blue light-emitting element. An anode electrode of the light-emitting element EL may be electrically connected to the driving element DT and disposed in its corresponding light-emitting area in each pixel. The light-emitting element EL is driven and emits light when a current from the driving element DT is generated, and the light is emitted to the outside of the display panel through the light-emitting area.

The driving element DT may generate a current according to the gate-source voltage to drive the light-emitting element EL. The driving element DT includes a gate electrode connected to a first node N1, a first electrode connected to a second node N2, and a second electrode connected to a third node N3. A capacitor C is connected between the first node N1 and the third node N3. The second node N2 is connected to the driving voltage line VDDL. The third node N3 is connected to an anode electrode of the light-emitting element EL. A cathode electrode of the light-emitting element EL is connected to a low-potential voltage line VSSL to which the low-potential voltage EVSS is applied.

A first switch element T1 is connected between the data line DL and the first node N1. The first switch element T1 is turned on in response to the gate pulse SCAN. When the first switch element T1 is turned on, the data voltage Vdata of the pixel data is applied to the first node N1, thereby writing the pixel data to the sub-pixel. The first switch element T1 may include a gate electrode connected to the gate line GL, a first electrode connected to the data line DL, and a second electrode connected to the first node N1.

The second switch element T2 is connected between the third node N3 and the reference voltage line RL. The second switch element T2 is turned on in response to the gate pulse SCAN. When the second switch element T2 is turned on, the third node N3 is connected to the reference voltage line RL. The second switch element T2 may include a gate electrode connected to the gate line GL, a first electrode connected to the third node N3, and a second electrode connected to the reference voltage line RL.

The driving element DT should have uniform electrical characteristics across all sub-pixels; however, due to process deviations and device characteristic deviations, differences in electrical characteristics may exist between sub-pixels, and these differences may increase as the sub-pixel driving time elapses. To compensate for these deviations in the electrical characteristics of the driving element DT, an external compensation circuit may be applied to the display panel driving circuit.

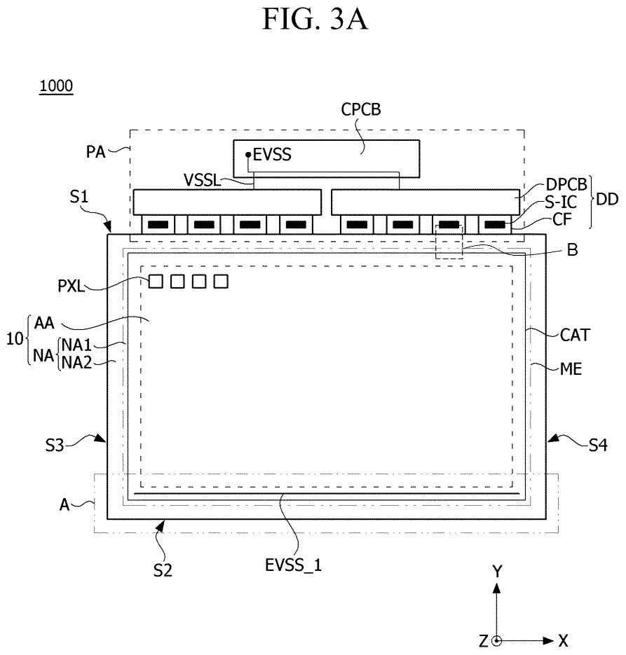

FIG. 3A is a plan view of a display panel 100 according to an example embodiment of the present specification. FIG. 3B is an enlarged plan view of area A of FIG. 3A, and FIG. 3C is an enlarged plan view of area B of FIG. 3A.

As shown in FIGS. 3A to 3C, the display panel 100 according to an example embodiment may include a substrate 10, a pad PA arranged at a first side S1 of the substrate 10, a low-potential voltage pattern EP and EVSS_1 arranged on the substrate 10 and electrically connected to the pad PA, a conductive encapsulation layer ME arranged on the low-potential voltage pattern EP and EVSS_1, and a connection structure CA configured to electrically connect the low-potential voltage pattern EP and EVSS_1 and the conductive encapsulation layer ME.

The display panel 100 may display information, video, and/or images provided to a user. For example, the display panel 100 may include a display area AA and a peripheral area NA adjacent to the display area AA. The peripheral area NA may also be referred to as the non-display are. In another example, the substrate 10 may include the display area AA and the peripheral area NA.

The display panel 100 may be formed in any of various shapes. The display panel 100 may have sides including a first side S1, a second side S2, a third side S3, and a fourth side S4. In this case, the first side S1 is formed along the X-axis direction (X) of the display panel 100 and may be the side at which the pad PA configured to transfer various signals to the display area AA is arranged. The second side S2 is formed along the X-axis direction (X) of the display panel 100 and may be the opposite side or the other side of the first side S1. The third side S3 may be a side formed along the Y-axis direction (Y) of the display panel 100 between the first side S1 and the second side S2. The fourth side S4 is formed along the Y-axis direction (Y) of the display panel 100 between the first side S1 and the second side S2 and may be the opposite side or the other side of the third side S3. However, the shape of the display panel 100 according to an embodiment of the present specification is not limited thereto, and the display panel 100 having four sides is described for the convenience of description. For example, the substrate 10 may include a flexible polymer film made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto.

The substrate 10 may be formed of an insulating material. For example, the substrate 10 may be formed of glass, resin, or the like. Also, the substrate 10 may be formed of a material having flexibility. For example, the substrate 10 may be formed of a plastic material having flexibility, such as Polyimide (PI) or the like. However, embodiments of the present specification are not limited thereto.

The display area AA may be an area in which an image is displayed. The display area AA of the substrate 10 or display panel 100 may be formed in any of various shapes depending on the design of the display device. For example, the display area AA may be formed in a rectangular shape having four rounded corners, but embodiments of the present specification are not limited thereto. In another example, the display area AA may be formed in a rectangular shape having four right-angled corners, a circular shape, or the like, but embodiments of the present specification are not limited thereto.

The display area AA may include a plurality of pixels PXL. The plurality of pixels PXL may be arranged in the form of a matrix by forming a plurality of rows and a plurality of columns, but the display panel of the present specification is not limited thereto.

Each of the plurality of pixels PXL may include a plurality of sub-pixels. Each of the plurality of sub-pixels may include at least one light-emitting element. Each of the plurality of pixels PXL may include sub-pixels configured to emit different colors. For example, the plurality of pixels PXL may include a red sub-pixel, a green sub-pixel, a blue sub-pixel, and a white sub-pixel. The types of the plurality of sub-pixels are illustrative, and embodiments of the present specification are not limited thereto.

The peripheral area NA may be an area in which an image is not displayed. In the peripheral area NA, various kinds of wires and driving circuits for driving the plurality of pixels PXL of the display area AA may be embedded, and the pad to which an integrated circuit, a printed circuit, and the like are connected may be arranged. However, embodiments of the present specification are not limited thereto. For example, in the peripheral area NA located along the first side S1 of the display panel 100, the pad PA configured to transfer signals to various kinds of signal wires and electrode patterns may be arranged.

The peripheral area NA may include a first peripheral area NA1 surrounding the display area AA and a second peripheral area NA2 surrounding the first peripheral area NA1.

The first peripheral area NA1 may be located around the display area AA so as to contact the outer line of the display area AA. The first peripheral area NA1 may be defined by the conductive encapsulation layer ME that functions as the encapsulant of the display panel. The first peripheral area NA1 may include a cathode electrode CAT, an auxiliary voltage line EVSS_1, and a connection pattern CP. However, the display panel 100 of the present specification is not limited thereto, and the first peripheral area NA1 may further include various signal wires and electrode patterns. Alternatively, in some cases, some components of the first peripheral area NA1 may be formed in the second peripheral area NA2 or may be formed across the first and second peripheral areas NA1 and NA2.

The second peripheral area NA2 may be located around the first peripheral area NA1 so as to contact the outer line of the first peripheral area NA1. The second peripheral area NA2 may include the edges of the display panel 100. The second peripheral area NA2 may include an electrode pattern EP, a connection member CM, and a heat-dissipating electrode HE. However, the display panel 100 of the present specification is not limited thereto, and the second peripheral area NA2 may further include various signal wires and electrode patterns. Alternatively, in some cases, some components of the second peripheral area NA2 may be formed in the first peripheral area NA1 or may be formed across the first and second peripheral areas NA1 and NA2.

The pad PA may include a timing controller on a control PCB CPCB and a data driver DD. The data driver DD may include a source IC S-IC, a circuit film CF, and a printed circuit board DPCB. FIGS. 3A to 3C show the circuit to which a low-potential voltage EVSS is supplied, omit a circuit to which gate pulses are supplied, and show signal lines SL in connection with the circuits to which signals of a pixel driving voltage, a data voltage, a reference voltage, and the like are supplied. Also, in FIGS. 3A to 3C, the circuit to which the low-potential voltage EVSS is supplied is not limited to that illustrated, and additional circuit patterns for applying the low-potential voltage EVSS may be further formed.

The low-potential voltage EVSS may be supplied from the timing controller on the control PCB CPCB to the cathode electrode CAT formed in the display panel 100 via the data driver DD. The low-potential voltage EVSS may be a ground voltage of 0 volt (0 V). As a result, even though the conductive encapsulation layer ME and the auxiliary voltage line EVSS_1 are connected, which may not cause a significant difference in sensing.

The data driver DD may include the printed circuit board DPCB connected to the timing controller on the control PCB CPCB at one side and the circuit film CF attached to the substrate 10 at the other side. The circuit film CF may include the source IC S-IC mounted thereon, and the printed circuit board DPCB may be connected to one end of the circuit film that is not attached to the substrate 10.

A low-potential voltage line VSSL for supplying the low-potential voltage EVSS may be formed. The low-potential voltage line VSSL may be connected to the low-potential voltage pattern EP and EVSS_1 arranged in the substrate 10 via the control PCB CPCB, the printed circuit board DPCB, the circuit film CF, and the source IC S-IC.

The electrode pattern EP may supply the low-potential voltage EVSS to the cathode electrode CAT by being connected to the cathode electrode CAT. The low-potential voltage pattern EP and EVSS_1 may include the auxiliary voltage line EVSS_1 and the electrode pattern EP.

The electrode pattern EP may be arranged between a plurality of circuit films CF spaced apart from each other. As shown in FIG. 3C, the electrode pattern EP may supply the low-potential voltage EVSS to the cathode electrode CAT by being connected to the circuit film CF. Specifically, the electrode pattern EP may include a first electrode pattern portion EP1 connected to the circuit film CF and a second electrode pattern portion EP2 that overlaps the cathode electrode CAT. An insulating layer is interposed between the second electrode pattern portion EP2 and the cathode electrode CAT, so the second electrode pattern portion EP2 may contact the cathode electrode CAT through a contact hole formed in the insulating layer.

As described above, the electrode pattern EP may be the path through which the low-potential voltage EVSS moves between the pad PA and the cathode electrode CAT. Here, the first electrode pattern portion EP1 of the electrode pattern EP is integrated in a limited space, which may increase current density. As a result, a combustion phenomenon may occur in the display panel 100 due to heat generation in the pad PA.

Also, when the display panel is driven by double-rate driving (DRD), the number of circuit films CF may be reduced compared to when it is driven by 1-Gate 1-Data (1G1D). In this case, compared to the display panel driven by 1G1D, the display panel driven by DRD may have a reduced number of electrode patterns EP, but the number of signal wires SL may be configured at a comparable level. For this reason, the display panel driven by DRD may have a limitation in increasing the area of the first electrode pattern portion EP1 connected to the circuit film CF. As a result, in the display panel driven by DRD, the heating temperature of the pad PA may further increase.

Accordingly, the display panel 100 according to an embodiment of the present specification may electrically connect the low-potential voltage pattern EVSS_1 and EP, which is electrically connected to the pad PA, to the conductive encapsulation layer ME covering the entire display area AA. The display panel 100 of the present specification lowers the current density of the low-potential voltage EVSS by electrically connecting the conductive encapsulation layer ME having a relatively large area to the low-potential voltage pattern EP and EVSS_1, thereby decreasing the heating temperature of the display panel. Here, the conductive encapsulation layer ME and the low-potential voltage pattern EP and EVSS_1 may be electrically connected through the connection structure CA.

The auxiliary voltage line EVSS_1 may be supplied with the low-potential voltage EVSS from the pad PA. The auxiliary voltage line EVSS_1 extends from the pad PA and may be arranged in the peripheral area NA located along the second side S2, opposite the first side S1 at which the pad PA is arranged. For example, the auxiliary voltage line EVSS_1 may be arranged along the first peripheral area NA1 at the second side S2.

However, the location of the auxiliary voltage line EVSS_1 according to an embodiment of the present specification is not limited to the first peripheral area NA1.

The auxiliary voltage line EVSS_1 may be electrically connected to the cathode electrode CAT. For example, the auxiliary voltage line EVSS_1 may be spaced apart from the cathode electrode CAT in a longitudinal or lateral direction and electrically connected to the cathode electrode CAT through the connection pattern CP. Also, the cathode electrode CAT may be contacted along the auxiliary voltage line EVSS_1, without being limited to that illustrated.

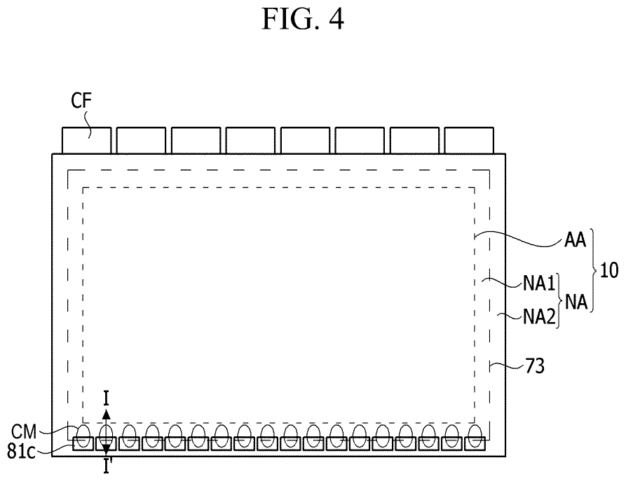

The cathode electrode CAT may be arranged in the display area AA and the first peripheral area NA1. The cathode electrode CAT may include a cathode electrode extension (85a in FIG. 5) of the light-emitting element, which extends from the display area AA to the first peripheral area NA1. The cathode electrode extension 85a may overlap portion of the first peripheral area NA1.

The cathode electrode CAT may be electrically connected to the low-potential voltage pattern EP and EVSS_1. For example, the cathode electrode CAT may be electrically connected to the electrode pattern EP at the first side S1 of the substrate 10 and may be electrically connected to the auxiliary voltage line EVSS_1 at the second side S2 of the substrate 10.

The cathode electrode CAT may be electrically connected to the low-potential voltage pattern EP and EVSS_1 through various structures. For example, the cathode electrode CAT may be supplied with the low-potential voltage EVSS by directly contacting the electrode pattern EP at the first side S1. For example, the cathode electrode CAT may be electrically connected to the auxiliary voltage line EVSS_1 through the connection pattern CP at the second side S2.

The connection structure CA may electrically connect the conductive encapsulation layer ME and the auxiliary voltage line EVSS_1. The connection structure CA may include the heat-dissipating electrode HE, the connection member CM, and the connection pattern CP.

The display panel according to an embodiment of the present specification may connect the conductive encapsulation layer ME, which functions as the encapsulant of the display panel, to the wire (e.g., auxiliary voltage line EVSS_1) arranged between the conductive encapsulation layer ME and the substrate 10.

However, the connection structure CA embodied in the present specification is merely an example for connecting the conductive encapsulation layer ME and the low-potential voltage pattern EP and EVSS_1 and may have any of various structures to connect the conductive encapsulation layer ME and the low-potential voltage pattern EP and EVSS_1, without being limited to the disclosed structure.

The connection pattern CP may electrically connect the auxiliary voltage line EVSS_1 and the heat-dissipating electrode HE. The connection pattern CP may be configured such that one side thereof is connected to the auxiliary voltage line EVSS_1 and the other side thereof is connected to the heat-dissipating electrode HE. At the same time, the connection pattern CP may be connected to the cathode electrode CAT at any one portion thereof. Such a connection pattern CP may be located to reach the second peripheral area NA2 via the first peripheral area NA1. Also, the connection pattern CP may contact the cathode electrode CAT along the auxiliary voltage line EVSS_1.

For example, the connection pattern CP may be arranged in the first peripheral area NA1 along the second side S2, which is opposite the first side S1 at which the pad PA is arranged.

The heat-dissipating electrode HE may be one of components for electrically connecting the auxiliary voltage line EVSS_1 and the conductive encapsulation layer ME. Such a heat-dissipating electrode HE may include a plurality of heat-dissipating electrodes. The plurality of heat-dissipating electrodes HE may be arranged in the second peripheral area NA2 along the second side S2 at which the pad PA is not formed. In some cases, the heat-dissipating electrodes HE may partially overlap the first peripheral area NA1. However, the location of the heat-dissipating electrodes HE in the display panel 100 of the present specification is not limited thereto, and may be variously arranged in the peripheral area NA.

Also, the heat-dissipating electrodes HE may be further arranged at the third side S3 or the fourth side S4 depending on the location of the pad including the circuit to which a gate pulse is supplied (e.g., the gate driver 120 in FIG. 1). For example, when the pad is further included at the third side S3 or the fourth side S4, the heat-dissipating electrode HE may be arranged in the second peripheral area NA2 located at the third side S3 or the fourth side S4. If the pad is included at both the third and fourth sides S3 and S4, the heat-dissipating electrode HE may be arranged only at the second side S2 as shown in FIG. 3B.

Two heat-dissipating electrodes HE may be formed for each circuit film CF. However, the display panel 100 of the present specification is not limited thereto. For example, one heat-dissipating electrode HE may be formed for each circuit film CF, or three or more heat-dissipating electrodes HE may be formed for each circuit film CF.

The connection member CM may electrically connect the heat-dissipating electrode HE and the conductive encapsulation layer ME. The connection member CM may be configured such that one side thereof is connected to the heat-dissipating electrode HE and the other side thereof is connected to the conductive encapsulation layer ME. Such a connection member CM may be formed to correspond to each of the plurality of heat-dissipating electrodes HE or to correspond to all of the plurality of heat-dissipating electrodes HE. The connection member CM may have various materials and shapes, and it will be specifically described in the following embodiments.

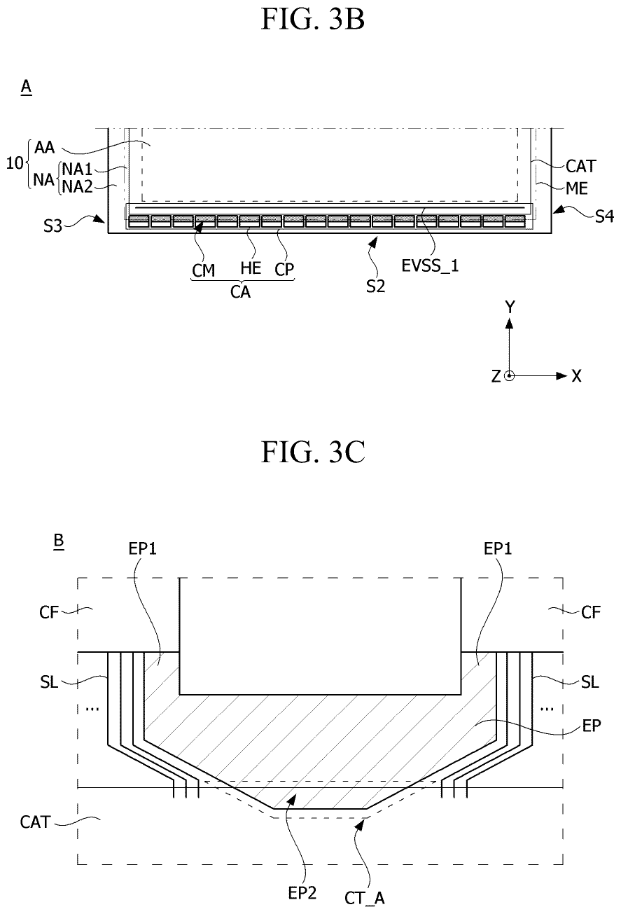

FIG. 4 is a plan view of a display panel according to a first example embodiment of the present specification, and FIG. 5 is a cross-sectional view taken along the line I-I′ in FIG. 4. Hereinafter, a description of the same components may be omitted.

As shown in FIGS. 4 and 5, the display panel according to the first example embodiment of the present specification may include a connection structure CA for electrically connecting a low-potential voltage pattern EP and EVSS_1 and a conductive encapsulation layer 73. The connection structure CA according to the first example embodiment may include a plurality of heat-dissipating electrodes 81c arranged at one side of a substrate 10 and connection members CM that are configured to contact the conductive encapsulation layer 73 and to correspond to the heat-dissipating electrodes 81c in a one-to-one manner.

As shown in FIG. 5, the display panel according to an example embodiment may include an auxiliary voltage line 21, first to fourth dams D1, D2, D3, and D4, and a connection electrode 81b in the first peripheral area NA1 and may include the heat-dissipating electrode 81c and the connection member CM in the second peripheral area NA2. Also, the display panel according to an embodiment may include an encapsulation layer structure 70 located in the display area AA and the first peripheral area NA1, a connection pattern 31 located in the first peripheral area NA1 and the second peripheral area NA2, and a fifth dam D5 located at the boundary between the first peripheral area NA1 and the second peripheral area NA2.

At least one dam may be arranged in the peripheral area NA. The at least one dam may include the first to fifth dams D1, D2, D3, D4, and D5. However, the display panel of the present specification is not limited thereto. For example, the at least one dam may include less than five dams or six or more dams.

Each of the first to fifth dams D1, D2, D3, D4, and D5 may be formed along the first peripheral area NA1. Each of the first to fifth dams D1, D2, D3, D4, and D5 may be arranged on an interlayer insulating layer 40. An insulating encapsulation layer 71 arranged on a bank 60 may have fluidity before being hardened since the material is applied in the formation process. Here, the display panel of the present specification may control the fluidity of the material of the insulating encapsulation layer 71 by arranging at least one dam in the peripheral area NA. In some cases, the first to fifth dams D1, D2, D3, D4, and D5 may also function to prevent or block foreign substances entering from outside the display panel from penetrating into the display area AA.

The first dam D1 may include a first layer 50a and a second layer 60a arranged on the first layer 50a. The second dam D2 may include a first layer 50b and a second layer 60b arranged on the first layer 50b. The third dam D3 may include a first layer 50c and a second layer 60c arranged on the first layer 50c. The fourth dam D4 may include a first layer 50d and a second layer 60d arranged on the first layer 50d. The fifth dam D5 may include a first layer 50e and a second layer 60e arranged on the first layer 50e.

Each of the first to fourth dams D1, D2, D3, and D4 may be configured such that a metal pattern 81a is arranged between the first layer 50a, 50b, 50c, or 50d and the second layer 60a, 60b, 60c, or 60d. The metal pattern 81a may be severed on the first layer 50a, 50b, 50c, or 50d and arranged in separate spaces in each of the first to fourth dams D1, D2, D3, and D4. Such a metal pattern 81a may be the same layer as the first electrode 81 of a light-emitting element 80. However, the display panel of the present specification is not limited thereto. For example, the metal pattern 81a may be omitted.

The connection pattern 31 may be arranged on an insulating layer 30 across the first and second peripheral areas NA1 and NA2. The connection pattern 31 may be connected to the auxiliary voltage line 21 through an open contact portion of the insulating layer 30. Also, the connection pattern 31 may be connected to the connection electrode 81b and heat-dissipating electrode 81c in the respective openings of the interlayer insulating layer 40. For example, the connection pattern 31 may contact the connection electrode 81b through a first contact portion CT1 and may contact the heat-dissipating electrode 81c through a second contact portion CT2.

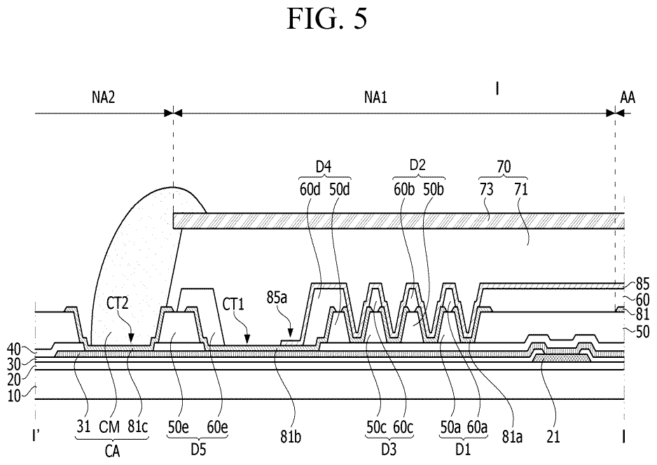

Accordingly, through the connection pattern 31, a low-potential voltage EVSS supplied to the auxiliary voltage line 21 may be transferred to a cathode electrode 85 and the conductive encapsulation layer 73. Such a connection pattern 31 may be formed as the same layer as the gate electrode 31a of at least one transistor (Tr in FIG. 6) arranged in the display area AA. However, the connection pattern 31 according to an embodiment of the present specification is not limited thereto.

The cathode electrode 85 may include a cathode electrode extension 85a extending from the display area AA to the first peripheral area NA1. The cathode electrode extension 85a contacts the respective second layers 60a, 60b, 60c, and 60d of the first to fourth dams D1, D2, D3, and D4 and may be arranged in the first peripheral area NA1. Also, the cathode electrode extension 85a may contact the metal pattern 81a arranged between the first to fourth dams D1, D2, D3, and D4.

The cathode electrode extension 85a may contact the connection electrode 81b. Accordingly, the cathode electrode 85 may be supplied with the low-potential voltage EVSS from the auxiliary voltage line 21.

The connection electrode 81b may be arranged between the fourth dam D4 and the fifth dam D5. The connection electrode 81b may be formed as the same layer as the anode electrode 81 of the light-emitting element 80. In this case, the connection electrode 81b may be formed also on the top and side surfaces of the first layer 50d of the fourth dam D4 and on the top and side surfaces of the first layer 50e of the fifth dam D5. However, the display panel of the present specification is not limited thereto.

The connection electrode 81b may electrically connect the connection pattern 31 and the cathode electrode 85. The connection electrode 81b may contact the connection pattern 31 in the opening of the interlayer insulating layer 40. Accordingly, the cathode electrode 85 connected to the connection electrode 81b and the auxiliary voltage line 21 connected to the connection pattern 31 may be electrically connected. As a result, the cathode electrode 85 that contacts the connection electrode 81b may be supplied with the low-potential voltage EVSS from the auxiliary voltage line 21.

However, the connection structure or connection component between the cathode electrode 85 and the auxiliary voltage line 21 according to an embodiment of the present specification is not limited thereto. For example, the cathode electrode 85 may directly contact the auxiliary voltage line 21 by forming a contact hole in the bank 60 and an overcoat layer 50.

The heat-dissipating electrode 81c includes a plurality of heat-dissipating electrodes and may be arranged at one side of the second peripheral area NA2. The heat-dissipating electrode 81c may be formed as the same layer as the anode electrode 81 of the light-emitting element 80. However, the display panel of the present specification is not limited thereto.

The heat-dissipating electrode 81c may electrically connect the connection pattern 31 and the connection member CM. The heat-dissipating electrode 81c may contact the connection pattern 31 in the opening of the interlayer insulating layer 40. Accordingly, the connection member CM connected to the heat-dissipating electrode 81c and the auxiliary voltage line 21 connected to the connection pattern 31 may be electrically connected. However, the connection structure or connection component between the conductive encapsulation layer 73 and the auxiliary voltage line 21 according to an embodiment of the present specification is not limited thereto.

The connection member CM according to the first embodiment may be configured to correspond to each of the plurality of heat-dissipating electrodes 81c. Accordingly, the connection member CM according to the first embodiment may include a plurality of connection members. The connection member CM according to the first embodiment may be a dot-shaped electrode. The connection member CM formed to have a dot shape may be configured such that one side thereof contacts the top surface, side surface, and bottom surface of the conductive encapsulation layer 73 at the edge of the conductive encapsulation layer 73, the bottom surface being opposite the top surface, and such that the other side thereof contacts the heat-dissipating electrode 81c. Accordingly, one side of the connection member CM may be connected to the conductive encapsulation layer 73 and the other side thereof may be connected to the heat-dissipating electrode 81c.

For example, the connection member CM according to the first embodiment may be formed of materials such as silver dot (Ag dot), gold dot (Au dot), copper dot (Cu dot), platinum dot (Pt dot), aluminum dot (Al dot), and the like. For example, silver dot (Ag dot) may be selected as a material with good electrical conductivity for the connection member CM. However, the display panel of the present specification is not limited thereto, and the connection member CM may be formed of various materials having conductivity.

The encapsulation layer 70 may be arranged in the display area AA and the peripheral area NA. The encapsulation layer 70 may include the insulating encapsulation layer 71 adjacent to the substrate 10 and the conductive encapsulation layer 73 arranged on the insulating encapsulation layer 71. Such an encapsulation layer 70 may protect the circuits formed in the display panel 100.

The insulating encapsulation layer 71 may be located in the display area AA, the first peripheral area NA1, and portion of the second peripheral area NA2. The insulating encapsulation layer 71 may bond the conductive encapsulation layer 73 to the display panel. The insulating encapsulation layer 71 may planarize the step difference formed by the light-emitting element 80, the plurality of dams D1, D2, D3, D4, and D5, and the like on the substrate 10. Also, the insulating encapsulation layer 71 may have a predetermined thickness to prevent or suppress electrical interference between the conductive encapsulation layer 73 and the light-emitting element 80.

For example, the insulating encapsulation layer 71 may be formed of olefin-based rubber. For example, the insulating encapsulation layer 71 may be formed of any one of Ethylene Propylene Dein Monomer (EPDM) and Polyolefin Elastomer (POE). However, the material of the insulating encapsulation layer 71 is not limited thereto.

The conductive encapsulation layer 73 may be located in the display area AA and the first peripheral area NA1. The conductive encapsulation layer 73 may define the first peripheral area NA1. The conductive encapsulation layer 73 may effectively block the penetration of oxygen and moisture, compared to the insulating encapsulation layer. Accordingly, the conductive encapsulation layer 73 may minimize or reduce the penetration of oxygen and moisture into the light-emitting element 80.

For example, the conductive encapsulation layer 73 may be formed of a material including any one of nickel (Ni), iron (Fe), and copper (Cu). For example, the conductive encapsulation layer 73 may be formed of an alloy of nickel (Ni) and iron (Fe). In another example, the conductive encapsulation layer 73 may be formed of a material such as copper (Cu) or a copper-based alloy.

The conductive encapsulation layer 73 may be electrically connected to the auxiliary voltage line 21 through the connection structure CA. Accordingly, the low-potential voltage EVSS is connected to the conductive encapsulation layer 73, which has a relatively large area compared to the low-potential voltage pattern EP and EVSS_1, whereby heat generation caused by the low-potential voltage pattern EP and EVSS_1 may be reduced. However, the connection structure CA or connection component between the conductive encapsulation layer 73 and the auxiliary voltage line 21 according to an embodiment of the present specification is not limited thereto.

FIG. 6 is a cross-sectional view of a light-emitting element according to an example embodiment.

As shown in FIG. 6, the display area AA may include a light-emitting element 80 provided in each of a plurality of sub-pixels PXL and at least one transistor Tr configured to drive the light-emitting element 80. On the substrate 10, a circuit element, which includes various signal wires for data signals and gate signals, transistors such as a switching thin-film transistor and a driving thin-film transistor, a capacitor, and the like, may be formed for each sub-pixel. Although a single transistor Tr configured to drive a single light-emitting element 80 is illustrated in FIG. 6 for the convenience of description, the display device of the present specification may include one or more transistors Tr.

The transistor Tr may include an active layer 33, a gate electrode 31a that overlaps the channel region 33c of the active layer 33 by arranging a gate insulating layer 30b on the active layer 33 to be interposed therebetween, and a source electrode 41 and a drain electrode 43 connected to a source region 33a and a drain region 33b, respectively, at opposite sides of the active layer 33.

The active layer 33 may have the source region 33a and the drain region 33b at opposite sides with the channel region 33c therebetween. Each of the source region 33a and the drain region 33b may be formed of a semiconductor material doped with n-type or p-type dopants. The channel region 33c that overlaps the gate electrode 31a may be formed of a semiconductor material that is not doped with n-type or p-type dopants.

The gate electrode 31a may overlap the channel region 33c of the active layer 33 with the same width, with the gate insulating layer 30b therebetween. For example, the gate electrode 31a may be a single layer or multiple layers formed of any one of molybdenum (Mo), aluminum (Al), chromium (Cr), gold (Au), titanium (Ti), nickel (Ni), neodymium (Nd), and copper (Cu) or an alloy thereof.

The gate insulating layer 30b may be formed of an inorganic insulating material, and may be formed of, for example, a silicon oxide layer (SiOₓ), a silicon nitride layer (SiNₓ), or a silicon oxynitride layer (SiOₓN_{y}), or a multilayer film thereof.

On the interlayer insulating layer 40, the source electrode 41 and the drain electrode 43 may be provided as the same layer. The source electrode 41 and the drain electrode 43 are respectively connected to the source region 33a and drain region 33b of the active layer 33 through contact holes. For example, the source electrode 41 and the drain electrode 43 may be formed as a single layer of a metal material such as molybdenum (Mo), aluminum (Al), chromium (Cr), gold (Au), titanium (Ti), nickel (Ni), neodymium (Nd) or copper (Cu) or an alloy thereof, or may be formed as a multilayer structure using the same.

Meanwhile, a light-shielding layer 21a may be arranged below the active layer 33 by overlapping at least the channel region 33c of the active layer 33 of the transistor Tr. The light-shielding layer 21a may prevent or block external light from passing through the substrate 10 and reaching the transistor Tr. For example, the light-shielding layer 21a may be formed as a single layer of a metal material such as molybdenum (Mo), titanium (Ti), aluminum-neodymium (AlNd), aluminum (Al), or chromium (Cr) or an alloy thereof, or may be formed as a multilayer structure using the same.

A first buffer layer (first insulating layer) 20 may be arranged below the light-shielding layer 21a, and a second buffer layer (second insulating layer) 30a may be arranged on the light-shielding layer 21a. The gate insulating layer (second insulating layer) 30b, the interlayer insulating layer (third insulating layer) 40, and an overcoat layer 50 may be sequentially arranged on the second buffer layer 30a.

The first buffer layer (first insulating layer) 20 may be arranged between the substrate 10 and the light-shielding layer 21a. The first buffer layer 20 may be arranged across the display area AA, first peripheral area NA1, and second peripheral area NA2 of the substrate 10. For example, the first buffer layer 20 may be formed as a single-layer or bilayer structure with silicon oxide (SiOₓ) or silicon nitride (SiNₓ).

The second buffer layer (second insulating layer) 30a may cover the light-shielding layer 21a and expose portion of an auxiliary voltage line 21, and may be arranged on the first buffer layer 20. The second buffer layer 30a may be arranged across the display area AA, first peripheral area NA1, and second peripheral area NA2 of the substrate 10.

The gate insulating layer (second insulating layer) 30b may expose portion of the source and drain regions 33a and 33b of the active layer 33 and portion of the auxiliary voltage line 21, and may be arranged on the second buffer layer 30a. The gate insulating layer 30b may be arranged across the display area AA, the first peripheral area NA1, and the second peripheral area NA2.

The interlayer insulating layer (third insulating layer) 40 may expose portion of each of the source and drain regions 33a and 33b of the active layer 33 and cover the gate electrode 31a. For example, the interlayer insulating layer 40 may be formed of an inorganic insulating material. In this case, the interlayer insulating layer 40 may be formed as a single layer or multiple layers of a silicon oxide layer (SiOₓ), a silicon nitride layer (SiNₓ), and a silicon oxynitride layer (SiOₓN_{y}).

The overcoat layer 50 may be arranged on the interlayer insulating layer 40. The overcoat layer 50 may be formed to have a thickness sufficient to planarize the surface step of the upper portion of the transistor Tr and may be formed as an organic insulating layer. For example, the overcoat layer 50 is a type of organic insulating layer, which may be any one of photo acryl, polyimide, benzocyclobutene resin, and acrylate, and may be formed as multiple layers in some cases.

A passivation layer may be further arranged between the interlayer insulating layer 40 and the overcoat layer 50. The passivation layer may protect the transistor Tr by covering the same.

The light-emitting element 80 may be arranged on the overcoat layer 50. The light-emitting element 80 may include a stacked structure of a first electrode 81, an intermediate layer 83, and a second electrode 85. When current supplied from a low-potential voltage line VSL flows in the second electrode 85 and when high-voltage current is supplied from the transistor Tr to the first electrode 81, an electric field is formed between the first electrode 81 and the second electrode 85, whereby the light-emitting element 80 may be driven such that light is emitted from the intermediate layer 83.

Here, a light-emitting portion is a region from which light is emitted in the light-emitting element 80, and may be a region exposed from a bank 60. However, the display panel of the present specification is not limited thereto, and the light-emitting portion may include the side and top surfaces of the bank 60, which may include the intermediate layer 83.

The first electrode 81 is provided in each sub-pixel PXL and may be electrically connected to the transistor Tr. When the display panel of the present specification is of a top emission type, the first electrode may be formed as a conductive layer formed of a transparent material. For example, the first electrode 81 may be formed of a transparent conductive material such as Indium Tin Oxide (ITO) or Indium Zinc Oxide (IZO).

The intermediate layer 83 may be provided on the top surface of the first electrode 81, which is open by the bank 60, and on the side and top surfaces of the bank 60. The intermediate layer 83 may be provided across the entire display area AA of the substrate 10.

The intermediate layer 83 may indicate a single stack of organic layer with multiple layers, which include a hole injection layer HIL, a hole transport layer HTL, a light-emitting layer EML, an electron transport layer ETL, and an electron injection layer EIL. In some cases, the intermediate layer 83 may have a tandem structure including a plurality of stacks (a first stack and a second stack), each of which has a light-emitting layer, and a charge generation layer (CGL) between the stacks. Also, the tandem structure of the intermediate layer 83 may be formed to have a plurality of stacks including three or more stacks, without being limited to the two-stack structure.

The charge generation layer may be formed as a bilayer of n-type and p-type layers. The n-type charge generation layer and p-type charge generation layer of the charge generation layer may include n-type dopants and p-type dopants, respectively.

The second electrode 85 may be arranged across the entire display area AA to face the first electrode 81. In addition, the second electrode 85 may also be arranged in the first and second peripheral areas NA1 and NA2 to contact the circuit components formed in the first and second peripheral areas NA1 and NA2.

When the display panel of the present specification is of a top emission type, the second electrode 85 may be formed to have higher reflection efficiency than the first electrode 81 such that it reflects light emitted from the intermediate layer 83. For example, the second electrode 85 may be formed as a multilayer structure including a transparent conductive layer and an opaque conductive layer having high reflection efficiency. The transparent conductive layer of the second electrode 85 may be formed of a material having a relatively high work function, such as Indium Tin Oxide (ITO) or Indium Zinc Oxide (IZO). The opaque conductive layer of the second electrode 85 may be formed as a single layer or multiple layers including any one selected from the group consisting of silver (Ag), aluminum (Al), copper (Cu), molybdenum (Mo), titanium (Ti), nickel (Ni), chromium (Cr), or tungsten (W) or an alloy thereof. For example, the second electrode 85 may be formed as a structure in which a transparent conductive layer, an opaque conductive layer, and a transparent conductive layer are sequentially stacked, or may be formed as a structure in which a transparent conductive layer and an opaque conductive layer are sequentially stacked.

The bank 60 covers the edge of the first electrode 81 and may be arranged on the overcoat layer 50. The bank 60 may include an opening that exposes the first electrode 81 to form the light-emitting portion of the light-emitting element 80. For example, the bank 60 may be formed of an organic material such as polyimide, acrylate, benzocyclobutene series resin, and the like.

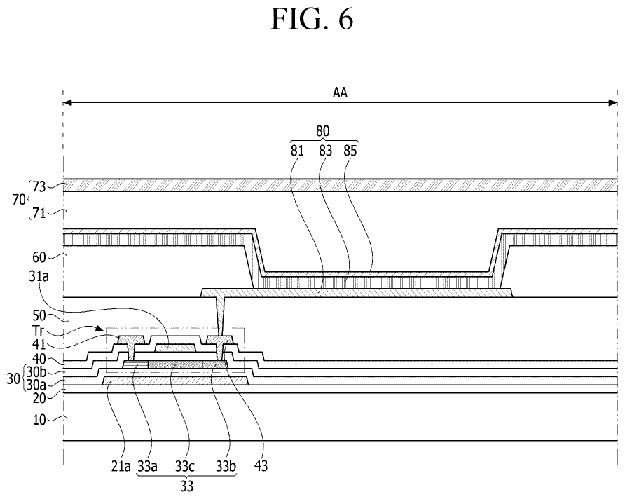

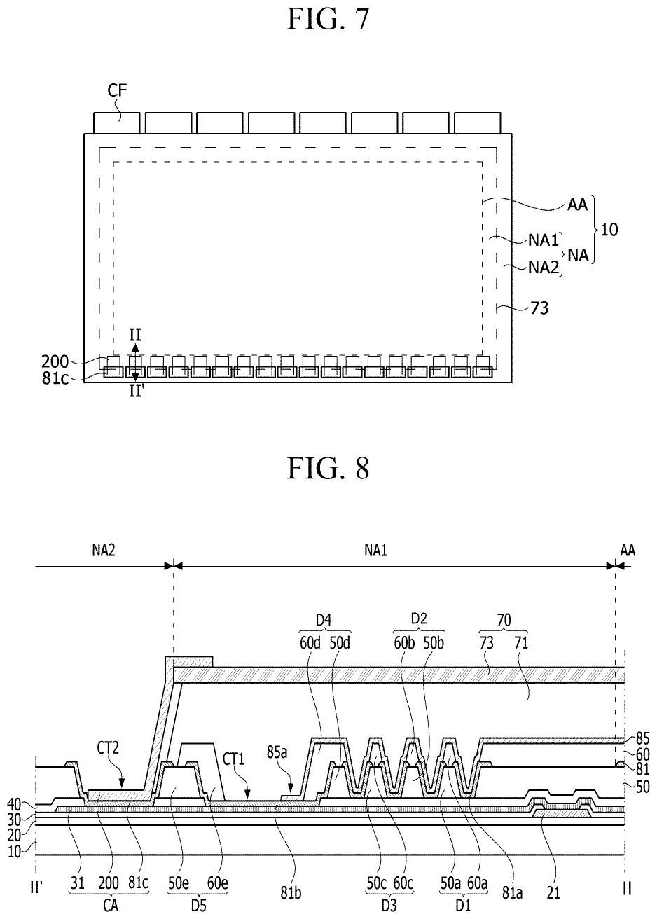

FIG. 7 is a plan view of a display panel according to a second example embodiment of the present specification, and FIG. 8 is a cross-sectional view taken along the line II-II′ in FIG. 7. A description of components that are the same as those in the previous example embodiment(s) may be omitted.

As shown in FIGS. 7 and 8, the display panel according to the second example embodiment of the present specification may include a connection structure CA for electrically connecting the low-potential voltage pattern EP and EVSS_1 and the conductive encapsulation layer 73. The connection structure CA according to the second embodiment may include a plurality of heat-dissipating electrodes 81c arranged at one side of the substrate 10 and connection members 200 configured to contact the conductive encapsulation layer 73 and correspond to the heat-dissipating electrodes 81c in a one-to-one manner.

The connection member 200 according to the second embodiment may be configured to correspond to each of the plurality of heat-dissipating electrodes 81c. Accordingly, the connection member 200 according to the second embodiment may include a plurality of connection members. The connection member 200 according to the second embodiment may be a conductive tape. The connection member 200 in the form of a conductive tape may be configured such that one side thereof is attached to the edge of the conductive encapsulation layer 73 and the other side thereof is attached to the heat-dissipating electrode 81c.

For example, the connection member 200 according to the second example embodiment may be any one of a copper (Cu) conductive tape, an aluminum conductive tape, a carbon conductive tape, a nickel conductive tape, and a silver conductive tape. However, the connection member 200 of the present specification is not limited thereto, and may be a tape formed of various materials having conductivity.

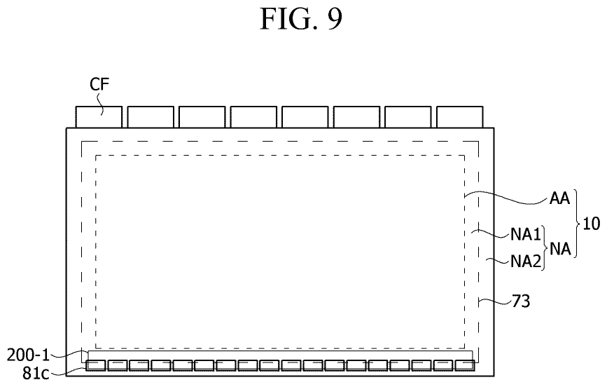

FIG. 9 is a plan view of a display panel according to a third example embodiment of the present specification.

As shown in FIG. 9, the display panel according to the third example embodiment of the present specification may include a connection structure CA for electrically connecting the low-potential voltage pattern EP and EVSS_1 and the conductive encapsulation layer 73. The connection structure CA according to the third embodiment may include a plurality of heat-dissipating electrodes 81c arranged at one side of the substrate 10 and a connection member 200-1 configured to contact the conductive encapsulation layer 73 and correspond to the plurality of heat-dissipating electrodes 81c.

The connection member 200-1 according to the third embodiment may be configured to correspond to the plurality of heat-dissipating electrodes 81c. Such a connection member 200-1 may be formed along the longitudinal direction at one side of the substrate 10 along which the plurality of heat-dissipating electrodes 81C are arranged. For example, a single connection member 200-1 may be formed to overlap all of the plurality of heat-dissipating electrodes 81c.

The connection member 200-1 according to the third example embodiment may be a dot-shaped electrode or a conductive tape, or may be another type of connection member formed of a conductive material. The connection member of the present specification is not limited to those illustrated.

The connection structure CA and the connection member 200 or 200-1 embodied in the present specification are merely the means for electrically connecting a low-potential voltage pattern and a conductive encapsulation layer, and the display panel according to one or more example embodiments of the present specification may have various components and structures for electrically connecting the low-potential voltage pattern and the conductive encapsulation layer.

Accordingly, the display panel according to one or more example embodiments of the present specification electrically may connect the low-potential voltage pattern to the conductive encapsulation layer having a relatively large area, thereby having the effect of reducing heat generation of a pad.

Although the example embodiments of the present disclosure have been described in more detail with reference to the accompanying drawings, the present disclosure is not necessarily limited to these embodiments, and various modifications may be made without departing from the technical spirit of the present disclosure.

Accordingly, the example embodiments disclosed in the present disclosure are not intended to limit the technical idea of the present disclosure, but are for illustrative purposes, and the scope of the technical idea of the present disclosure is not limited by these embodiments.

Therefore, it should be understood that the example embodiments described above are illustrative in all respects and not limiting.

In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display panel, comprising:
a substrate;
a pad arranged at a first side of the substrate;
a low-potential voltage pattern arranged on the substrate and electrically connected to the pad;
a conductive encapsulation layer arranged on the low-potential voltage pattern; and
a connection structure configured to electrically connect the low-potential voltage pattern and the conductive encapsulation layer.

2. The display panel of claim 1, wherein an area of the conductive encapsulation layer is larger than an area of the low-potential voltage pattern.

3. The display panel of claim 1, wherein a low-potential voltage supplied to the low-potential voltage pattern is 0 volt.

4. The display panel of claim 1, wherein:
the substrate includes a display area and a peripheral area surrounding the display area;
the low-potential voltage pattern includes an electrode pattern arranged in the peripheral area of the substrate at the first side and an auxiliary voltage line arranged along the peripheral area of the substrate in which the electrode pattern is not arranged; and
the conductive encapsulation layer is located in the display area and the peripheral area and is electrically connected to the auxiliary voltage line through the connection structure.

5. The display panel of claim 4, wherein the connection structure comprises:
a heat-dissipating electrode arranged in the peripheral area of the substrate;
a connection pattern configured such that a first side thereof is connected to the auxiliary voltage line and a second side thereof is connected to the heat-dissipating electrode; and
a connection member configured such that a first side thereof is connected to the conductive encapsulation layer and a second side thereof is connected to the heat-dissipating electrode.

6. The display panel of claim 5, wherein:
the peripheral area includes a first peripheral area surrounding the display area and a second peripheral area surrounding the first peripheral area;
the conductive encapsulation layer is located in the display area and the first peripheral area;
the auxiliary voltage line is located in the first peripheral area;
the connection pattern is located across the first and second peripheral areas; and
the heat-dissipating electrode is located in the second peripheral area.

7. The display panel of claim 5, wherein the connection member is a dot-shaped electrode or a conductive tape.

8. The display panel of claim 4, wherein:
the substrate includes a display area including a plurality of pixels;
each of the plurality of pixels includes a light-emitting element arranged between the substrate and the conductive encapsulation layer; and
a cathode electrode of the light-emitting element is electrically connected to each of the electrode pattern and the auxiliary voltage line.

9. The display panel of claim 8, wherein the cathode electrode further includes a cathode electrode extension extending from the display area to the peripheral area and connected to the auxiliary voltage line.

10. The display panel of claim 8, further comprising:
an insulating encapsulation layer between the conductive encapsulation layer and the light-emitting element.

11. A display panel, comprising:
a substrate including a display area, a first peripheral area, and a second peripheral area, wherein the first peripheral area is between the display area and the second peripheral area;
a pad arranged at a first side of the substrate;
an auxiliary voltage line arranged on the first peripheral area of the substrate and electrically connected to the pad;
a heat-dissipating electrode arranged on the second peripheral area of the substrate;
a connection pattern arranged on the first and second peripheral areas of the substrate and configured such that a first side thereof is connected to the auxiliary voltage line and a second side thereof is connected to the heat-dissipating electrode;
a conductive encapsulation layer located in the display area and first peripheral area of the substrate and arranged over the auxiliary voltage line; and
a connection member configured such that a first side thereof is connected to the heat-dissipating electrode and a second side thereof is connected to the conductive encapsulation layer.

12. The display panel of claim 11, wherein the auxiliary voltage line is supplied with a low-potential voltage from the pad.

13. The display panel of claim 12, wherein the low-potential voltage is 0 volt.

14. The display panel of claim 12, further comprising:
an electrode pattern supplied with the low-potential voltage from the pad,
wherein the electrode pattern is arranged in the first peripheral area located along the first side, and
wherein the auxiliary voltage line is arranged along the first peripheral area located at a second side that is opposite the first side.

15. The display panel of claim 11, wherein the connection member is a dot-shaped electrode or a conductive tape.

16. The display panel of claim 11, wherein:
the display area includes a plurality of pixels,
each of the plurality of pixels includes a light-emitting element arranged between the substrate and the conductive encapsulation layer, and
a cathode electrode of the light-emitting element is electrically connected to the connection pattern and the auxiliary voltage line.

17. The display panel of claim 16, wherein the cathode electrode further includes a cathode electrode extension extending from the display area to the first peripheral area and connected to the auxiliary voltage line via the connection pattern.

18. A display panel, comprising:
a substrate;
a low-potential voltage pattern arranged on the substrate;
a conductive encapsulation layer arranged over the low-potential voltage pattern;
a plurality of pixels each including a light-emitting element arranged between the substrate and the conductive encapsulation layer; and
a connection structure configured to electrically connect the low-potential voltage pattern with the conductive encapsulation layer and a cathode electrode of the light-emitting element.

19. A display device including a display panel, wherein the display panel comprises:
a substrate;
a pad arranged at a first side of the substrate;
a low-potential voltage pattern arranged on the substrate and electrically connected to the pad;
a conductive encapsulation layer arranged on the low-potential voltage pattern; and
a connection structure configured to electrically connect the low-potential voltage pattern and the conductive encapsulation layer.
